(19) United States
(12) Patent Application Publication
(10) Pub. No.: US 2026/0130157 A1
(43) Pub. Date: May 7, 2026

(54) APPARATUS AND METHOD FOR CLEANING SEMICONDUCTOR WAFER

(71) Applicant: Taiwan Semiconductor Manufacturing Company. Ltd., Hsinchu (TW)

(72) Inventors: Yen-HAO CHEN, Taipei County (TW); Feng-Tao LEE, Miaoli County (TW); Yung-Lung HSU, Tainan (TW); Wen-Tung CHUANG, Hsinchu (TW)

(73) Assignee: Taiwan Semiconductor Manufacturing Company. Ltd., Hsinchu (TW)

(21) Appl. No.: 19/177,360

(22) Filed: Apr. 11, 2025

Related U.S. Application Data
(60) Provisional application No. 63/715,401, filed on Nov. 1, 2024.

(51) Int. Cl. H01L 21/67; F28C 3/00; G01K 1/02; H01L 21/02

(52) U.S. Cl. CPC H10P 72/0414; F28C 3/00; G01K 1/026; H10P 70/20

(57) ABSTRACT

The present disclosure describes a cleaning system using a cleaning liquid generated by a cooling system. and a second flow rate of the second liquid coolant based on a temperature of the second die. The cleaning system includes a cooling system configured to generate a cleaning liquid, a controller configured to control a temperature of the cleaning liquid, a wafer holder configured to hold and rotate a wafer, a first nozzle above the wafer and configured to spray the cleaning liquid on a top surface of the wafer, and a second nozzle below the wafer and configured to spray the cleaning liquid on a bottom surface of the wafer.

### CROSS-REFERENCE TO RELATED APPLICATION

This application claims the benefit of U.S. Provisional Patent Application No. 63/715,401, titled “Apparatus and Method for Cleaning Semiconductor Wafer,” filed November 1, 2024, the disclosure of which is incorporated by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (FinFETs), gate-all-around field effect transistors (GAAFETs), and nanostructure transistors. Such scaling down has increased the complexity of semiconductor manufacturing process and increased the defects during the manufacturing process. A cleaning process is an important step in the manufacturing process to clean semiconductor wafers (e.g., silicon wafers). The yield of a silicon wafer is inversely related to the defect density (e.g., cleanliness and particle count) from wafer processing. An objective of the wafer cleaning process is to remove chemical and particle impurities without altering or damaging a wafer.

### BRIEF DESCRIPTION OF THE DRAWINGS

Aspects of the present disclosure are best understood from the following detailed description when read with the accompanying figures.

FIG. 1 illustrate a cross-sectional view of a cleaning system using a cleaning liquid generated by a cooling system, in accordance with some embodiments.

FIGS. 2, 3, and 4 illustrate partial cross-sectional views of a cooling system, in accordance with some embodiments.

FIG. 5 is a flow diagram of a method for cleaning a wafer with a cleaning system using a cleaning liquid generated by a cooling system, in accordance with some embodiments.

FIG. 6 is a flow diagram of a cleaning process for cleaning a wafer with a cleaning liquid generated by a cooling system, in accordance with some embodiments.

FIG. 7 illustrates an example computer system in which various embodiments of the present disclosure can be implemented.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20 % of the value (e.g., ±1 %, ±2 %, ±3 %, ±4 %, ±5 %, ±10 %, ±20 % of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices on a wafer (e.g., silicon substrate) continue to scale down. The continuous scaling down of device dimensions and the increasing demand for device performance may require various process improvements, which can have multiple challenges. For example, more layers of semiconductor devices and structures can be stacked on the wafer to improve device performance and reduce power consumption. The temperature of the wafer can increase after various semiconductor manufacturing processes. The temperature increase of the wafer can cause deformation of the wafer. With more layers of semiconductor structures stacked on the wafer, wafer deformation can become worse after these manufacturing processes. Increased wafer deformation can lead to defects such as unevenly deposited photoresist layer in subsequent processes, which can prevent photolithography tools to process the deformed wafer.

A cleaning process can clean a front-side surface, a backside surface, and edges of a wafer after various semiconductor manufacturing processes. The cleaning process can be an inline process using a room temperature cleaning liquid, such as room temperature deionized (DI) water. While the wafer may be cooled during the cleaning processes by the room temperature cleaning liquid, the temperature of the wafer may still be high to cause wafer deformation and warpage. The wafer deformation and warpage can increase the difficulty of subsequent photolithography processes and decrease the yield of the semiconductor devices.

Various embodiments in the present disclosure provide systems and methods for cleaning a wafer with a cleaning liquid generated by a cooling system. In some embodiments, a cleaning system can include a cleaning apparatus configured to clean a wafer with a cleaning liquid, a cooling system configured to generate the cleaning liquid, and a controller configured to control a temperature of the cleaning liquid. The cleaning apparatus can include a wafer holder configured to hold and rotate the wafer, a first nozzle above the wafer, and a second nozzle below the wafer. The first nozzle can be configured to spray the cleaning liquid on a top surface of the wafer. The second nozzle can be configured to spray the cleaning liquid on a bottom surface of the wafer. In some embodiments, the cleaning system can further include temperature sensors on the first and second nozzles to monitor the temperature of the cleaning liquid. In some embodiments, the temperature of the cleaning liquid can range from about 5 ℃ to about 15 ℃. In some embodiments, the cleaning liquid can cool the wafer and reduce wafer deformation. As a result, the uniformity of subsequently-deposited photolithography layer on the wafer can increase. The increase of photolithography layer uniformity can improve the yield of semiconductor devices on wafer 104. Additionally, the temperature of the cleaning liquid can be controlled above about 5 ℃ to avoid wafer cracks from fast temperature changes of the wafer during the cleaning process.

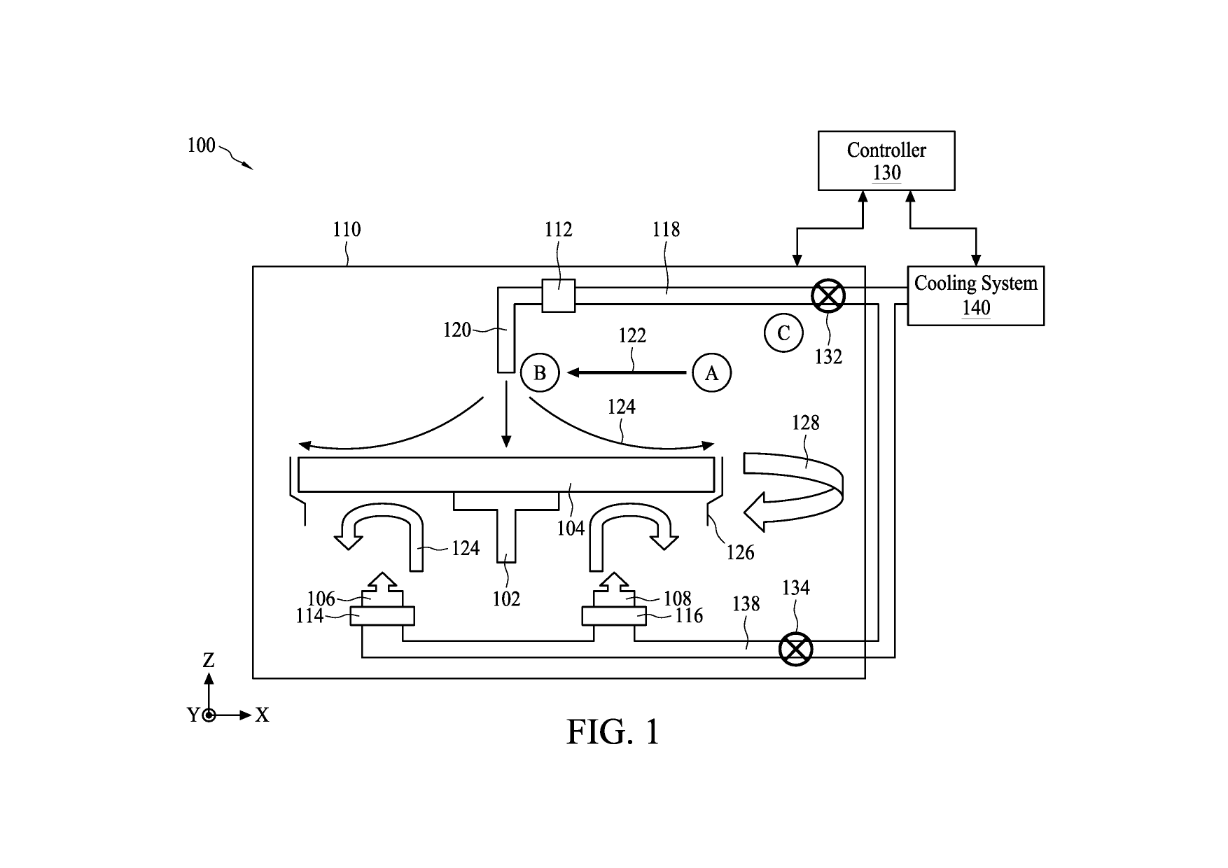

FIGS. 1-4 illustrate partial cross-sectional views of various embodiments of a cleaning system 100 using a cleaning liquid generated by a cooling system, in accordance with some embodiments. In some embodiments, as shown in FIG. 1, cleaning system 100 can include a cleaning apparatus 110, a controller 130, and a cooling system 140. In some embodiments, cleaning apparatus 110 can include a wafer holder 102, a wafer 104, nozzles 106, 108, and 120, temperature sensors 112, 114, and 116, pipes 118 and 138, and valves 132 and 134. In some embodiments, cleaning system 100 can be configured to clean wafer 104 with cleaning liquid 124 generated by cooling system 140. The discussion of elements of cooling system 100 in FIGS. 1-4 with the same annotations applies to each other, unless mentioned otherwise. And like reference numerals generally indicate identical, functionally similar, and/or structurally similar elements.

In some embodiments, wafer holder 102 can be an electrostatic wafer chuck and configured to hold and rotate wafer 104 during the cleaning process. In some embodiments, as shown in FIG. 1, wafer holder 102 can include pins 126 surrounding wafer 104 to prevent wafer 104 from sliding during the cleaning process. In some embodiments, wafer holder 102 can rotate wafer 104 during the cleaning process. In some embodiments, arrow 128 can indicate a direction of wafer holder 102 to rotate wafer 104. In some embodiments, wafer holder 102 can rotate wafer 104 at a speed from about 100 rounds per minute (rpm) to about 1000 rpm to spread cleaning liquid 124 across wafer 104 and remove any residues and particles on the surface of wafer 104. If the speed is greater than about 1000 rpm, wafer cracks may occur and semiconductor devices and structures on wafer 104 may be damaged. If the speed is less than about 100 rpm, cleaning liquid may not be uniformly spread across wafer 104 and residues and particles may remain on wafer 104 after the cleaning process.

In some embodiments, wafer 104 can be a semiconductor wafer having semiconductor devices and structures, such as logic devices, memory devices, and interconnects, formed on its surfaces. In some embodiments, wafer 104 can include a semiconductor material, such as silicon. In some embodiments, wafer 104 includes a crystalline silicon substrate (e.g., silicon wafer). In some embodiments, wafer 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, wafer 104 can be doped depending on design requirements (e.g., p-type substrate or n-type substrate). In some embodiments, wafer 104 can be doped with p-type dopants (e.g., boron, indium, aluminum, or gallium) or n-type dopants (e.g., phosphorus or arsenic).

In some embodiments, wafer 104 can go through various manufacturing processes which can include annealing processes, deposition processes, or other high thermal processes. After these high thermal manufacturing processes, wafer 104 can have a temperature greater than about 300 ℃. In some embodiments, the high temperature of wafer 104 greater than about 300 ℃ can cause wafer deformation and lead to wafer warpage, which can cause further problems to subsequent lithography processes. In some embodiments, wafer warpage can cause the edge of wafer 104 to bend upward or downward relative to the center of wafer 104. In some embodiments, wafer warpage can lead to a height difference d between the center and the edge of wafer 104 greater than about 300 µm. Large height difference d (e.g., greater than about 300 µm) can cause problems to subsequent lithography processes. In some embodiments, height difference d of wafer warpage can range from about 300 µm to about 600 µm. In some embodiments, if height difference d is greater than about 600 µm, wafer cracks can occur and the semiconductor devices and structures on wafer 104 can be damaged. In some embodiments, if height difference d is less than about 300 µm, wafer warpage may not cause problems to subsequent lithography processes.

In some embodiments, as shown in FIG. 1, cleaning liquid 124 can be sprayed on a top surface of wafer 104 by nozzle 120 and sprayed on a bottom surface of wafer 104 by nozzles 106 and 108. In some embodiments, cleaning liquid 124 can include cold DI water generated by cooling system 140. In some embodiments, cleaning liquid 124 can include any suitable cleaning fluids, such as but not limited to, DI water, ultrapure water, isopropyl alcohol (IPA), hydrogen peroxide, ammonium hydroxide, acids, acetone, methanol, or any combinations thereof. In some embodiments, cleaning liquid 124 flowing out of nozzle 120 and nozzles 106 and 108 can include a same cleaning liquid. In some embodiments, cleaning liquid 124 flowing out of nozzle 120 and nozzles 106 and 108 can include different cleaning liquids.

In some embodiments, a temperature of cleaning liquid 124 can be less than room temperature. In some embodiments, the temperature of cleaning liquid 124 can range from about 5 ℃ to about 15 ℃ to reduce the wafer warpage. If the temperature of cleaning liquid 124 is greater than about 15 ℃, cleaning liquid 124 may not reduce height difference d of wafer warpage below about 300 µm. If the temperature of cleaning liquid 124 is less than about 5 ℃, the cleaning process may cause a fast temperature change of wafer 104 and may lead to wafer cracks of wafer 104. In some embodiments, the temperature of cleaning liquid 124 can range from about 8 ℃ to about 10 ℃ to further reduce the height difference d of wafer warpage and reduce wafer cracks. In some embodiments, when the temperature of cleaning liquid 124 ranges from about 8 ℃ to about 10 ℃, wafer 104 after the cleaning process can have substantially no wafer warpage and no wafer cracks. With the temperature of cleaning liquid 124 lowered by cooling system 140, wafer deformation and warpage of wafer 104 can be reduced, the uniformity of subsequent photolithography layer on wafer 104 can be improved, and the yield of the semiconductor devices on wafer 104 can be increased.

In some embodiments, nozzle 120 can be disposed above the top surface of wafer 104 and nozzles 106 and 108 can be disposed below the bottom surface of wafer 104. In some embodiments, the top surface of wafer 104 can be a front-side surface and can have various semiconductor devices and structures. In some embodiments, the bottom surface of wafer 104 can be a back-side surface and can have fewer or substantially no semiconductor devices. In some embodiments, nozzle 120 can move across the top surface of wafer 104 while spraying cleaning liquid 124 at a preset flow rate to the top surface of wafer 104. For example, as shown in FIG. 1, nozzle 120 can move during a cleaning cycle from the edge of wafer 104, such as position A, to the center of wafer 104, such as position B, and back to an original position (also referred to as “home”), such as position C. In some embodiments, the movement of nozzle 120 during the cleaning cycle can be indicated by arrow 122. In some embodiments, as shown in FIG. 1, nozzles 106 and 108 can be disposed on opposite sides of wafer holder 102 below wafer 104. In some embodiments, nozzles 106 and 108 can spray cleaning liquid 124 at a preset flow rate to the bottom surface of wafer 104. In some embodiments, nozzles 106 and 108 may not move while spraying cleaning liquid 124. In some embodiments, wafer holder 102 can hold and rotate wafer 104 while nozzles 120, 106, and 108 spray cleaning liquid 124 on the top and bottom surfaces of wafer 104. Though three nozzles 120, 106, and 108 are shown in FIG. 1, cleaning apparatus 110 can have any number of nozzles to dispense cleaning liquid 124 on wafer 104.

In some embodiments, the cleaning cycle can include additional steps and each step can last from about 5 seconds to about 15 seconds. In some embodiments, the cleaning cycle can include 8 steps to 10 steps. In some embodiments, the steps in the cleaning cycle can include using different nozzles, such as nozzles 120, 106, and 108, to clean various surfaces of wafer 104. In some embodiments, the steps in the cleaning cycle can include using one nozzle, such as nozzle 120, to clean different locations of wafer 104. In some embodiments, the steps in the cleaning cycle can include dispensing cleaning liquid 124 at different flow rates. In some embodiments, wafer 104 can be rotated while being cleaned with cleaning liquid 124. In some embodiments, wafer 104 can be turned upside down for cleaning during the cleaning cycle. In some embodiments, cleaning liquid 124 can be used in each step of the cleaning cycle.

In some embodiments, as shown in FIG. 1, temperature sensors 112, 114, and 116 can be disposed on nozzles 120, 106, and 108, respectively. In some embodiments, temperature sensors 112, 114, and 116 can measure the temperature of cleaning liquid 124 flowing out of nozzles 120, 106, and 108, respectively. In some embodiments, if the temperature of cleaning liquid 124 is out of a specific range, such as from about 5 ℃ to about 15 ℃, controller 130 can control cooling system 140 to decrease or increase the temperature of cleaning liquid 124 to be within the specific range. Though three temperature sensors 112, 114, and 116 are shown in FIG. 1, cleaning apparatus 110 can have any number of temperature sensors to measure the temperature of cleaning liquid 124 being sprayed on wafer 104.

In some embodiments, the temperature of cleaning liquid 124 flowing out of nozzle 120 can be different from the temperature of cleaning liquid 124 flowing out of nozzles 106 and 108. In some embodiments, cleaning liquid 124 dispensed by nozzle 120 to the top surface of wafer 104 can have a first temperature. Cleaning liquid 124 dispensed by nozzles 106 and 108 to the bottom surface of wafer 104 can have a second temperature. In some embodiments, the first temperature can be greater or substantially equal to the second temperature. In some embodiments, the first temperature can be less than the second temperature. In some embodiments, a temperature difference between the first temperature and the second temperature can range from about 0 ℃ to about 5 ℃. If the temperature difference is greater than about 5 ℃, wafer 104 may crack and semiconductor devices and structures on wafer 104 may be damaged. In some embodiments, the temperature difference of cleaning liquid 124 can be caused by different pipes 118 and 138 used to deliver cleaning liquid 124. In some embodiments, cooling system 140 can separately control the first temperature of cleaning liquid 124 delivered to nozzle 120 and the second temperature of cleaning liquid 124 delivered to nozzles 106 and 108.

In some embodiments, as shown in FIG. 1, cleaning liquid 124 can be delivered to nozzles 120 by pipe 118 and to nozzles 106 and 108 by pipe 138. In some embodiments, pipe 118 can include a valve 132 between cooling system 140 and nozzle 120. Pipe 138 can include a valve 134 between cooling system 140 and nozzles 106 and 108. In some embodiments, valves 132 and 134 can limit or adjust a flow rate of cleaning liquid 124 in pipes 118 and 138, respectively. In some embodiments, valves 132 and 134 can be controlled by controller 130 to adjust the flow rate of cleaning liquid 124. In some embodiments, the flow rate of cleaning liquid 124 can range from about 1 liter per minute (LPM) to about 8 LPM. In some embodiments, if the flow rate is less than about 1 LPM, particles may accumulate in cleaning liquid 124 and particles and residues may remain on wafer 104 after the cleaning process. Additionally, the temperature of cleaning liquid 124 may increase. If the flow rate is greater than about 8 LPM, cleaning liquid 124 sprayed on wafer 104 may damage the semiconductor devices and structures on wafer 104. In some embodiments, the flow rate of cleaning liquid 124 in pipe 118 can be different from or substantially the same as the flow rate of cleaning liquid 124 in pipe 138.

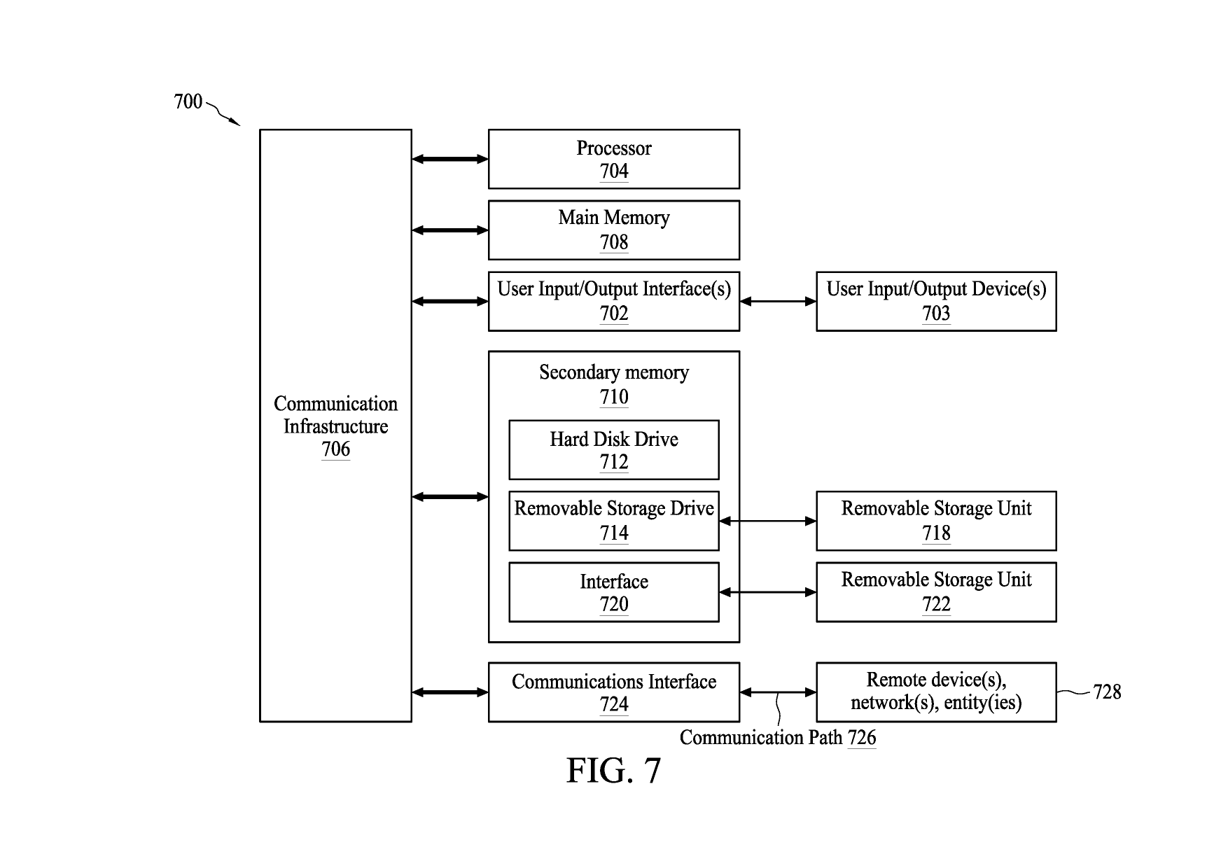

In some embodiments, as shown in FIG. 1, controller 130 can be connected to cleaning apparatus 110 and cooling system 140. In some embodiments, controller 130 can monitor the temperature of cleaning liquid 124 flowing out of nozzles 120, 106, and 108 with temperature sensors 112, 114, and 116, respectively. In some embodiments, controller 130 can control the flow rate of cleaning liquid 124 in pipes 118 and 138 with valves 132 and 134, respectively. In some embodiments, controller 130 can adjust the temperature of cleaning liquid 124 with cooling system 140. In some embodiments, controller 130 can control wafer holder 102 to hold and rotate wafer 104, while cleaning liquid 124 is being dispensed on wafer 104. In some embodiments, controller 130 can control nozzle 120 to move between position A, position B, and position C. In some embodiments, controller 130 can communicate with cleaning apparatus 110 and cooling system 140 over wired communication paths. In some embodiments, controller 130 can communicate with cleaning apparatus 110 and cooling system 140 over wireless communication paths. An embodiment of controller 130 is described in detail in FIG. 7.

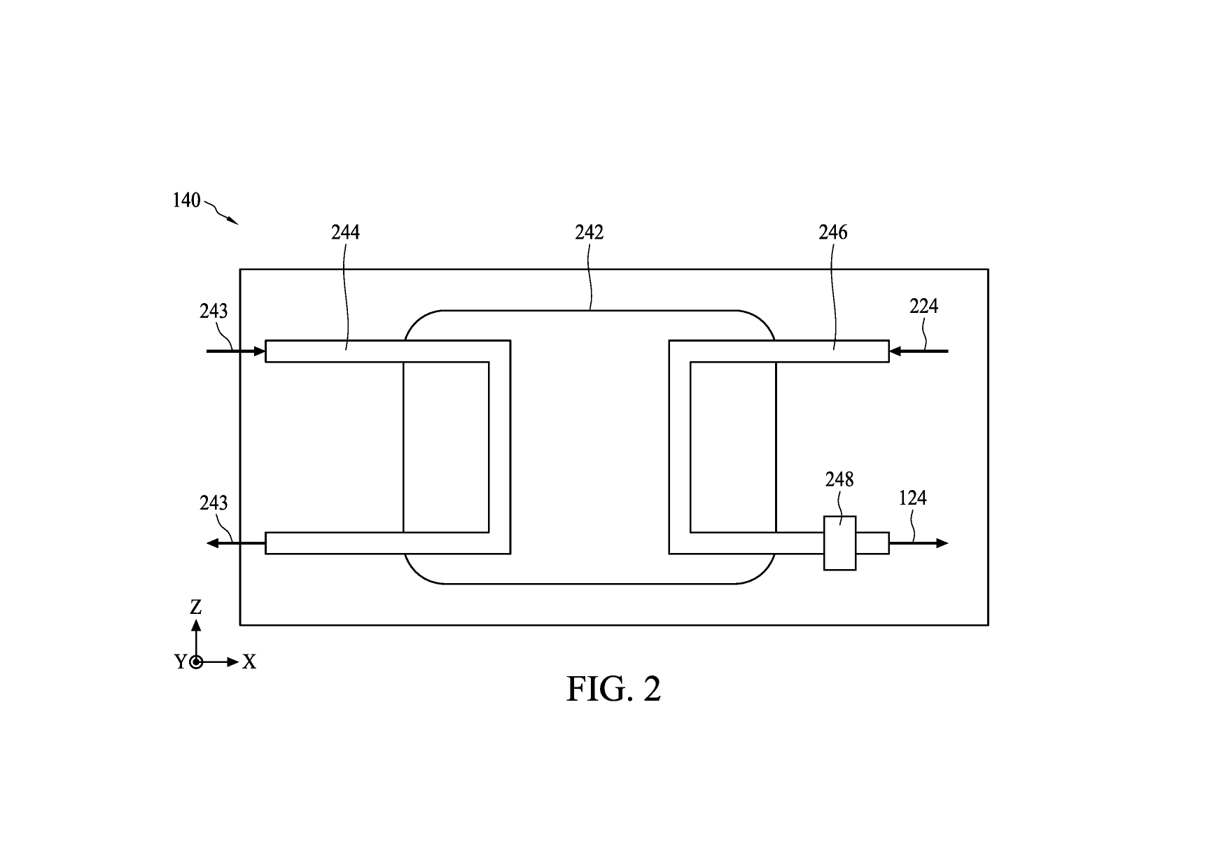

In some embodiments, as shown in FIG. 1, cooling system 140 can be connected to cleaning apparatus 110 and controller 130. In some embodiments, cooling system 140 can generate cleaning liquid 124 and provide cleaning liquid 124 to cleaning apparatus 110. In some embodiments, cooling system 140 can be controlled by controller 130 to adjust the temperature of cleaning liquid 124. In some embodiments, as shown in FIG. 2, cooling system 140 can include a cooling tank 242, a cleaning liquid pipe 246, and a refrigerant pipe 244. In some embodiments, cooling tank 242 can be filled with a coolant, such as glycol. In some embodiments, the coolant in cooling tank 242 can absorb heat from cleaning liquid pipe 246 and release heat to refrigerant pipe 244.

In some embodiments, cleaning liquid pipe 246 can generate cleaning liquid 124 from room temperature cleaning liquid 224. In some embodiments, as shown in FIG. 2, room temperature cleaning liquid 224 can flow into cleaning liquid pipe 246. The coolant in cooling tank 242 can absorb the heat of room temperature cleaning liquid 224 and lower the temperature of room temperature cleaning liquid 224. In some embodiments, cleaning liquid pipe 246 can include a Teflon tube and room temperature liquid 224 can include ultrapure water. In some embodiments, refrigerant 243 can flow through refrigerant pipe 244 and take away the heat of the coolant in cooling tank 242.

In some embodiments, as shown in FIG. 2, a temperature sensor 248 can be disposed on an exit of cleaning liquid pipe 246 to measure the temperature of generated cleaning liquid 124. In some embodiments, controller 130 can monitor the temperature of generated cleaning liquid 124 with temperature sensor 248. In some embodiments, controller 130 can control the temperature of cleaning liquid 124 flowing out of cleaning liquid pipe 246 by adjusting a flow rate of refrigerant 243 in refrigerant pipe 244. In some embodiments, cooling system 140 can include a temperature controller (not show) to control flow rates of room temperature cleaning liquid 224 and cleaning liquid 124 so as to control the temperature of cleaning liquid 124 flowing out of cleaning liquid pipe 246.

In some embodiments, the temperature of cleaning liquid 124 can range from about 5 ℃ to about 15 ℃ for cleaning apparatus 110 to reduce wafer warpage. If the temperature of cleaning liquid 124 is greater than about 15 ℃, cleaning liquid 124 may not reduce height difference d of wafer warpage below about 300 µm. If the temperature of cleaning liquid 124 is less than about 5 ℃, the cleaning process may cause a fast temperature change of wafer 104 and may lead to wafer cracks in wafer 104. In some embodiments, the temperature of cleaning liquid 124 can range from about 8 ℃ to about 10 ℃ to further reduce the height difference d of wafer warpage and reduce wafer cracks. In some embodiments, when the temperature of cleaning liquid 124 ranges from about 8 ℃ to about 10 ℃, wafer 104 after the cleaning process can have substantially no wafer warpage and no wafer cracks. With cleaning liquid 124 provided by cooling system 140, wafer deformation and warpage of wafer 104 can be reduced, the uniformity of subsequent photolithography layer on wafer 104 can be improved, and the yield of the semiconductor devices on wafer 104 can be increased.

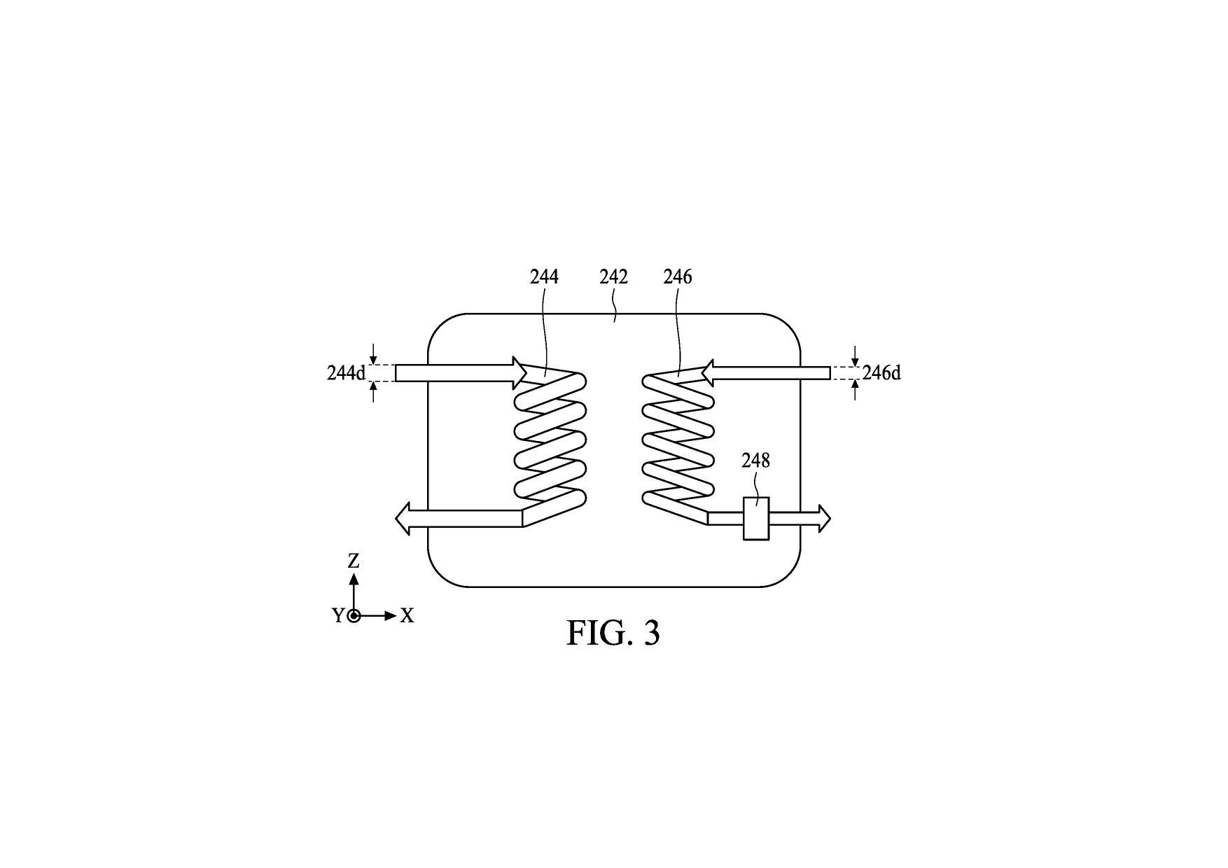

In some embodiments, as shown in FIG. 2, portions of cleaning liquid pipe 246 and refrigerant pipe 244 in cooling tank 242 can be bent. In some embodiments, as shown in FIG. 3, the portions of cleaning liquid pipe 246 and refrigerant pipe 244 in cooling tank 242 can be spiral. In some embodiments, the spiral shape can increase a contact area between the coolant and cleaning liquid pipe 246 as well as between the coolant and refrigerant pipe 244. The increase of the contact area can improve the heat exchange efficiency of cooling system 140 and the temperature control of cleaning liquid 124. In some embodiments, the portions of cleaning liquid pipe 246 and refrigerant pipe 244 in cooling tank 242 can be in other suitable configurations to increase the contact area.

In some embodiments, a diameter 244d of refrigerant pipe 244 can range from about 5 mm to about 10 mm for improved temperature control of cleaning liquid 124. If diameter 244d is less than about 5 mm, the temperature of cleaning liquid 124 may be higher about 15 ℃ and cleaning liquid 124 may not reduce wafer warpage. If diameter 244d is greater than about 10 mm, the temperature of cleaning liquid 124 may be lower than about 5 ℃ and cleaning liquid 124 may lead to wafer cracks and may cause damage to the semiconductor devices and structures on wafer 104.

In some embodiments, a diameter 246d of cleaning liquid pipe 246 can range from about 5 mm to about 20 mm. In some embodiments, a pressure of cleaning liquid 124 can range from about 2 kg/cm² to about 4 kg/cm². In some embodiments, if diameter 246d is less than about 5 mm or the pressure of cleaning liquid 124 is less than about 2 kg/cm², cooling system 140 may not provide sufficient amount of cleaning liquid 124 for the cleaning process. In some embodiments, if diameter 246d is greater than about 20 mm or the pressure of cleaning liquid 124 is greater than about 4 kg/cm², cleaning liquid 124 may lead to wafer cracks and may cause damage to the semiconductor devices and structures on wafer 104.

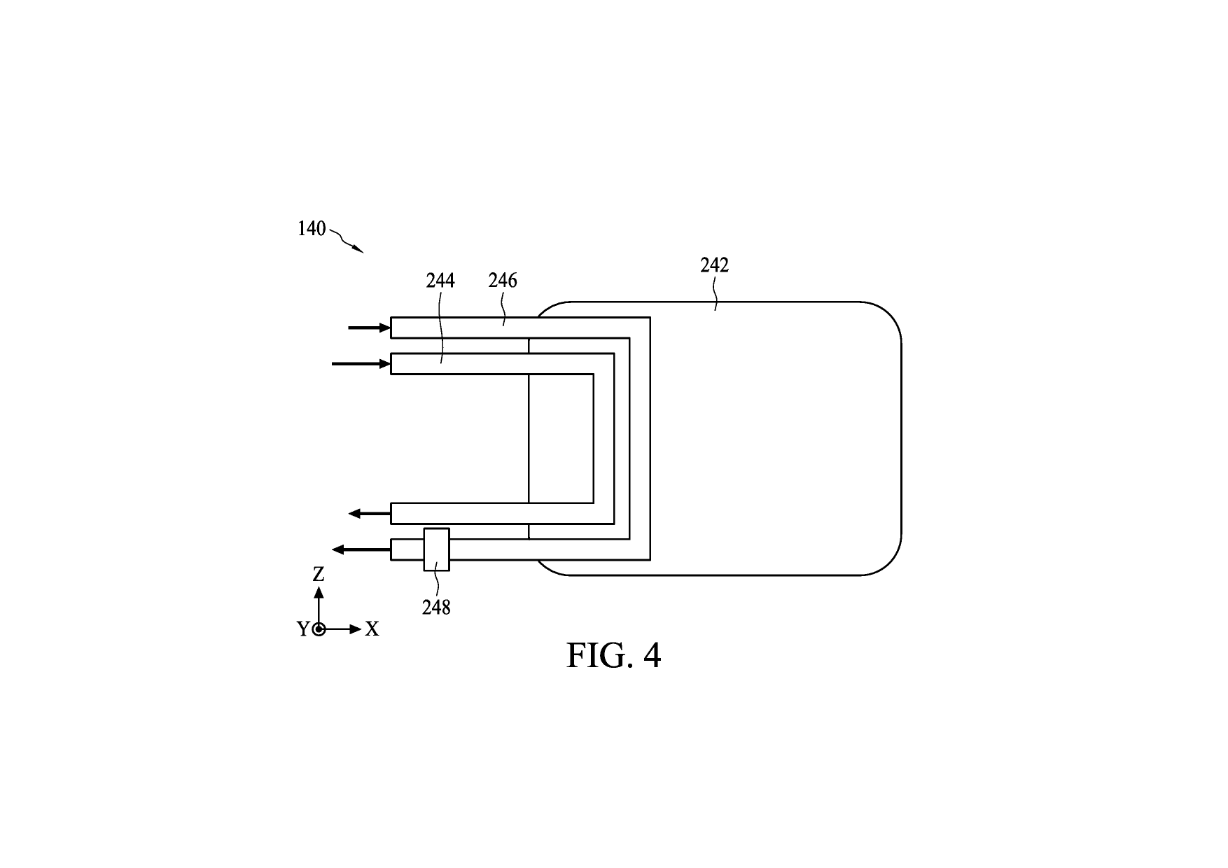

In some embodiments, as shown in FIGS. 2 and 3, cleaning liquid pipe 246 and refrigerant pipe 244 can be disposed on opposite sides of cooling tank 242. In some embodiments, as shown in FIG. 4, cleaning liquid pipe 246 and refrigerant pipe 244 can be disposed on the same side of cooling tank 242. In some embodiments, cleaning liquid pipe 246 and refrigerant pipe 244 can be disposed in other suitable configurations to generate cleaning liquid 124.

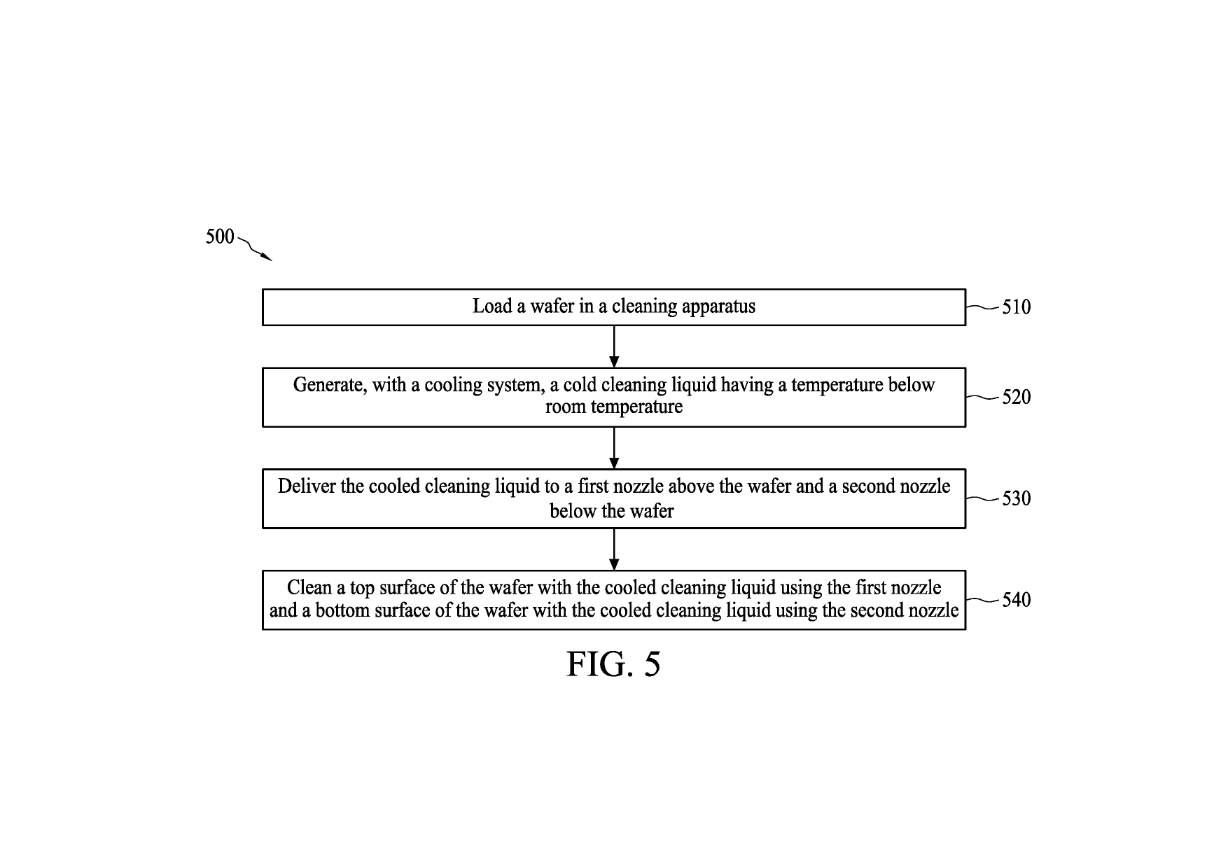

FIG. 5 is a flow diagram of a method 500 for a cleaning system to clean a wafer with a cleaning liquid generated by a cooling system, in accordance with some embodiments. Method 500 may not be limited to cleaning system 100 and can be applicable to other systems that would benefit from the cleaning liquid. Additional operations may be performed between various operations of method 500 and may be omitted merely for clarity and ease of description. Additional operations can be provided before, during, and/or after method 500; one or more of these additional operations are briefly described herein. Moreover, not all operations may be needed to perform the disclosure provided herein. Additionally, some of the operations may be performed simultaneously or in a different order than shown in FIG. 5. In some embodiments, one or more other operations may be performed in addition to or in place of the presently-described operations. For illustrative purposes, the operations illustrated in FIG. 5 will be described with reference to the example embodiments as illustrated in FIGS. 1-4.

In referring to FIG. 5, method 500 begins with operation 510 and the process of loading a wafer in a cleaning apparatus. For example, as shown in FIG. 1, wafer 104 can be loaded in cleaning apparatus 110. In some embodiments, wafer holder 102 can be configured to hold and rotate wafer 104. In some embodiments, as shown in FIG. 1, wafer holder 102 can include pins 126 surrounding wafer 104 to prevent wafer 104 from sliding during a cleaning process. In some embodiments, wafer holder 102 can rotate wafer 104 at a speed from about 100 rpm to about 1000 rpm to spread cleaning liquid 124 across wafer 104 and remove any residues and particles on the surface of wafer 104.

Referring to FIG. 5, in operation 520, a cleaning liquid is generated with a cooling system and has a temperature below room temperature. For example, as shown in FIGS. 1-4, cleaning liquid 124 can be generated by cooling system 140 and can have a temperature below room temperature. In some embodiments, cooling system 140 can generate cleaning liquid 124 from room temperature cleaning liquid 224. In some embodiments, cooling system 140 can include cooling tank 242, refrigerant pipe 244, and cleaning liquid pipe 246, as shown in FIGS. 2-4 to generate cleaning liquid 124. In some embodiments, temperature sensor 248 can be disposed on an exit of cleaning liquid pipe 246 to measure the temperature of generated cleaning liquid 124. In some embodiments, as shown in FIGS. 1-4, controller 130 can use temperature sensor 248 to monitor and control the temperature of generated cleaning liquid 124.

In some embodiments, the temperature of cleaning liquid 124 can range from about 5 ℃ to about 15 ℃ for cleaning apparatus 110 to reduce wafer warpage. If the temperature of cleaning liquid 124 is greater than about 15 ℃, cleaning liquid 124 may not reduce height difference d of wafer warpage below about 300 µm. If the temperature of cleaning liquid 124 is less than about 5 ℃, the cleaning process may cause a fast temperature change of wafer 104 and may lead to wafer cracks in wafer 104. In some embodiments, the temperature of cleaning liquid 124 can range from about 8 ℃ to about 10 ℃ to further reduce the height difference d of wafer warpage and reduce wafer cracks. In some embodiments, when the temperature of cleaning liquid 124 ranges from about 8 ℃ to about 10 ℃, wafer 104 after the cleaning process can have substantially no wafer warpage and no wafer cracks. With cleaning liquid 124 provided by cooling system 140, wafer deformation and warpage of wafer 104 can be reduced, the uniformity of subsequent photolithography layer on wafer 104 can be improved, and the yield of the semiconductor devices on wafer 104 can be increased.

Referring to FIG. 5, in operation 530, the cleaning liquid is delivered to a first nozzle above the wafer and a second nozzle below the wafer. For example, as shown in FIG. 1, cleaning liquid 124 can be delivered to nozzle 120 above wafer 104 and nozzles 106 and 108 below wafer 104. In some embodiments, cleaning liquid 124 can be delivered to nozzle 120 through pipe 118 and valve 132. In some embodiments, cleaning liquid 124 can be delivered to nozzles 106 and 108 through pipe 138 and valve 134. In some embodiments, controller 130 can control a flow rate of cleaning liquid 124 delivered to nozzle 120 and nozzles 106 and 108 via valves 132 and 134, respectively. In some embodiments, the flow rate of cleaning liquid 124 can range from about 1 LPM to about 8 LPM. In some embodiments, if the flow rate is less than about 1 LPM, particles may accumulate in cleaning liquid 124 and particles and residues may remain on wafer 104 after the cleaning process. Additionally, the temperature of cleaning liquid 124 may increase. If the flow rate is greater than about 8 LPM, cleaning liquid 124 sprayed on wafer 104 may damage the semiconductor devices and structures on wafer 104. In some embodiments, the flow rate of cleaning liquid 124 in pipe 118 can be different from or substantially the same as the flow rate of cleaning liquid 124 in pipe 138.

Referring to FIG. 5, in operation 540, a top surface of the wafer is cleaned with the cleaning liquid using the first nozzle and a bottom surface of the wafer is cleaned with the cleaning liquid using the second nozzle. For example, as shown in FIG. 1, the top surface of wafer 104 can be cleaned with cleaning liquid 124 using nozzle 120 and the bottom surface of wafer 104 can be cleaned with cleaning liquid 124 using nozzles 106 and 108. In some embodiments, nozzle 120 can move across the top surface of wafer 104 while cleaning the top surface of wafer 104 with cleaning liquid 124. For example, as shown in FIG. 1, nozzle 120 can move during a cleaning cycle from the edge of wafer 104, such as position A, to the center of wafer 104, such as position B, and back to a home position, such as position C. In some embodiments, controller 130 can control the movement of nozzle 120 as indicated by arrow 122 during the cleaning cycle.

In some embodiments, as shown in FIG. 1, nozzles 106 and 108 can be disposed on opposite sides of wafer holder 102 and can spray cleaning liquid 124 to the bottom surface of wafer 104. In some embodiments, nozzles 106 and 108 may not move while cleaning the bottom surface of wafer 104 with cleaning liquid 124. In some embodiments, nozzles 120, 106, and 108 can clean the top and bottom surfaces of wafer 104 with cleaning liquid 124 while wafer holder 102 holds and rotates wafer 104. In some embodiments, wafer holder 102 can rotate wafer 104 at a speed from about 100 rpm to about 1000 rpm to spread cleaning liquid 124 across wafer 104 and remove any residues and particles on the top and bottom surfaces of wafer 104.

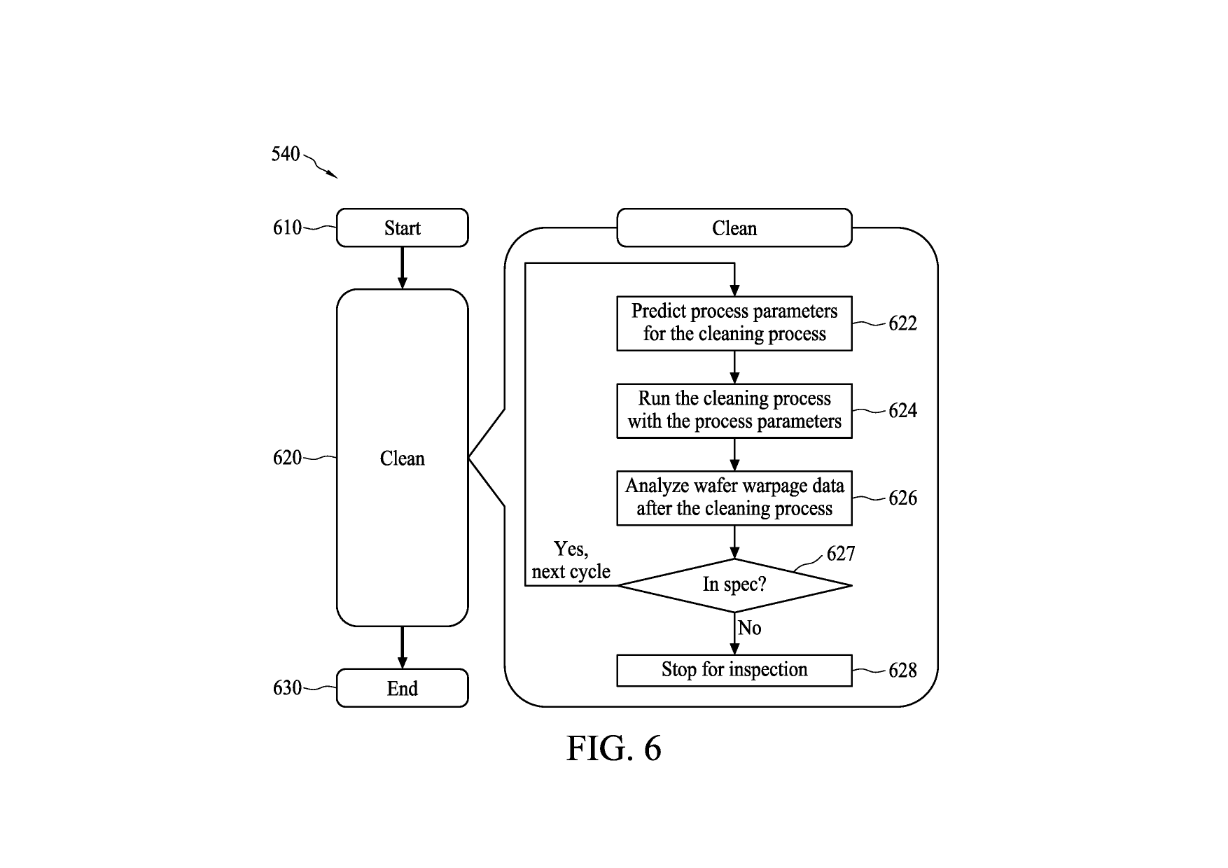

In some embodiments, operation 540 can be described in further details in FIG. 6. As shown in FIG. 6, the cleaning process can start in operation 610. In some embodiments, cleaning apparatus 110 can be initialized for the cleaning process in operation 610. In some embodiments, as shown in FIG. 1, cleaning apparatus 110 in operation 610 can move nozzle 120 from home position C to the edge of wafer 104 as indicated by position A.

In operation 620, the cleaning process can be performed. In some embodiments, the cleaning process can include one or more cleaning cycles. In some embodiments, each cleaning cycle can include operations 622, 624, 626, 627, and 628. In operation 622, the process parameters for the cleaning process can be predicted by controller 130. In some embodiments, the process parameters can include the temperature of cleaning liquid 124, the flow rate of cleaning liquid 124, the rotation speed of wafer holder 102, and other suitable process parameters. In some embodiments, the process parameters can be predicted based on previous wafer warpage data after the cleaning process. In some embodiments, the previous wafer warpage data can be collected after a front-side clean with cleaning liquid 124, a backside clean with cleaning liquid 124, and both front-side and backside clean with cleaning liquid 124. In some embodiments, the process parameters can be predicted based on prior semiconductor manufacturing processes performed on wafer 104. In some embodiments, the process parameters can be predicted using a machine learning model, a neural network model, or other suitable data models built with big data mining.

In operation 624, controller 130 can control cleaning apparatus 110 to run the cleaning process with the predicted process parameters. In some embodiments, controller 130 can control the temperature of cleaning liquid 124, the flow rate of cleaning liquid 124, the rotation speed of wafer holder 102, and other parameters of cleaning apparatus 110 according to the predicted process parameters.

In operation 626, controller 130 can analyze wafer warpage data of wafer 104 after the cleaning process. In some embodiments, the wafer warpage data can be measured in subsequent inline measurement tools after the cleaning process. In operation 627, controller 130 can check the wafer warpage data of wafer 104. If the wafer warpage data of wafer 104 is in spec, for example, if height difference d between the center and edge of wafer 104 is below about 300 µm, next cleaning cycle for additional wafers can continue with the predicted process parameters. If the wafer warpage data of wafer 104 is out of spec, for example, if height difference d is above about 300 µm, controller 130 can stop the cleaning process and cleaning apparatus 110 for inspection by a user.

In operation 630, controller 130 can end the cleaning process. In some embodiments, the cleaning process can end when all wafers have been cleaned. In some embodiments, the cleaning process can end when cleaning apparatus 110 is stopped for inspection and maintenance. In some embodiments, controller 130 can stop the rotation of wafer holder 102 and reduce the flow rate of cleaning liquid 124 to about 1 LPM after ending the cleaning process.

FIG. 7 is an illustration of an example computer system 700 in which various embodiments of the present disclosure can be implemented, according to some embodiments. Computer system 700 can be any well-known computer capable of performing the functions and operations described herein. For example, and without limitation, computer system 700 can be capable of controlling cooling system 140 to generate cleaning liquid 124 and controlling cleaning apparatus 110 to clean wafer 104 with cleaning liquid 124. Computer system 700 can be an example of controller 130, for example, to execute one or more operations in method 500 and method 600, which describe an example method for cleaning system 100 to clean wafer 104 with cleaning liquid 124 generated by cooling system 140.

Computer system 700 includes one or more processors (also called central processing units, or CPUs), such as a processor 704. Processor 704 is connected to a communication infrastructure or bus 706. Computer system 700 also includes input/output device(s) 703, such as monitors, keyboards, pointing devices, etc., that communicate with communication infrastructure or bus 706 through input/output interface(s) 702. A system control tool can receive instructions to implement functions and operations described herein—e.g., method 500 of FIG. 5—via input/output device(s) 703. Computer system 700 also includes a main or primary memory 708, such as random access memory (RAM). Main memory 708 can include one or more levels of cache. Main memory 708 has stored therein control logic (e.g., computer software) and/or data. In some embodiments, the control logic (e.g., computer software) and/or data can include one or more of the operations described above with respect to method 500 of FIG. 5.

Computer system 700 can also include one or more secondary storage devices or memory 710. Secondary memory 710 can include, for example, a hard disk drive 712 and/or a removable storage device or drive 714. Removable storage drive 714 can be a floppy disk drive, a magnetic tape drive, a compact disk drive, an optical storage device, tape backup device, and/or any other storage device/drive.

Removable storage drive 714 can interact with a removable storage unit 718. Removable storage unit 718 includes a computer usable or readable storage device having stored thereon computer software (control logic) and/or data. Removable storage unit 718 can be a floppy disk, magnetic tape, compact disk, DVD, optical storage disk, and/or any other computer data storage device. Removable storage drive 714 reads from and/or writes to removable storage unit 718 in a well-known manner.

In some embodiments, secondary memory 710 can include other means, instrumentalities or other approaches for allowing computer programs and/or other instructions and/or data to be accessed by computer system 700. Such means, instrumentalities or other approaches can include, for example, a removable storage unit 722 and an interface 720. Examples of the removable storage unit 722 and the interface 720 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. In some embodiments, secondary memory 710, removable storage unit 718, and/or removable storage unit 722 can include one or more of the operations described above with respect to method 500 of FIG. 5.

Computer system 700 can further include a communication or network interface 724. Communication interface 724 enables computer system 700 to communicate and interact with any combination of remote devices, remote networks, remote entities, etc. (individually and collectively referenced by reference number 728). For example, communication interface 724 can allow computer system 700 to communicate with remote devices 728 over communications path 726, which can be wired and/or wireless, and which can include any combination of LANs, WANs, the Internet, etc. Control logic and/or data can be transmitted to and from computer system 700 via communication path 726.

The operations in the preceding embodiments can be implemented in a wide variety of configurations and architectures. Therefore, some or all of the operations in the preceding embodiments—e.g., method 500 of FIG. 5—can be performed in hardware, in software or both. In some embodiments, a tangible apparatus or article of manufacture including a tangible computer useable or readable medium having control logic (software) stored thereon is also referred to herein as a computer program product or program storage device. This includes, but is not limited to, computer system 700, main memory 708, secondary memory 710 and removable storage units 718 and 722, as well as tangible articles of manufacture embodying any combination of the foregoing. Such control logic, when executed by one or more data processing devices (such as computer system 700), causes such data processing devices to operate as described herein.

Various embodiments in the present disclosure provide systems and methods for cleaning wafer 104 with cleaning liquid 124 generated by cooling system 140. In some embodiments, cleaning system 100 can include cleaning apparatus 110 configured to clean wafer 104 with cleaning liquid 124, cooling system 140 configured to generate cleaning liquid 124, and controller 130 configured to control a temperature of cleaning liquid 124. Cleaning apparatus 110 can include wafer holder 102 configured to hold and rotate wafer 104, nozzle 120 above wafer 104, and nozzles 106 and 108 below wafer 104. Nozzle 120 can be configured to spray cleaning liquid 124 on a top surface of wafer 104. Nozzles 106 and 108 can be configured to spray cleaning liquid 124 on a bottom surface of wafer 104. In some embodiments, cleaning system 100 can further include temperature sensors 112, 114, and 116 on nozzles 120, 106, and 108 to monitor the temperature of cleaning liquid 124. In some embodiments, the temperature of cleaning liquid 124 can range from about 5 ℃ to about 15 ℃. In some embodiments, cleaning liquid 124 can cool wafer 104 and reduce wafer deformation. As a result, the uniformity of subsequently-deposited photolithography layer on wafer 104 can increase. The increase of photolithography layer uniformity can improve the yield of semiconductor devices on wafer 104. Additionally, the temperature of cleaning liquid 124 can be controlled above about 5 ℃ to avoid wafer cracks from fast temperature changes of wafer 104 during the cleaning process.

In some embodiments, an apparatus includes a wafer holder configured to hold and rotate a wafer, a first nozzle above the wafer and configured to spray a first cleaning liquid on a top surface of the wafer, and a second nozzle below the wafer and configured to spray a second cleaning liquid on a bottom surface of the wafer. The first cleaning liquid is generated by a cooling system and a first temperature of the first cleaning liquid is below room temperature. The second cleaning liquid is generated by the cooling system and a second temperature of the second cleaning liquid is below room temperature.

In some embodiments, a method includes loading a wafer in a cleaning apparatus, generating, with a cooling system, a cleaning liquid having a temperature below room temperature, delivering the cleaning liquid to a first nozzle above the wafer and a second nozzle below the wafer, and cleaning a top surface of the wafer with the cleaning liquid using the first nozzle and a bottom surface of the wafer with the cleaning liquid using the second nozzle.

In some embodiments, a system includes a cooling system configured to generate a cleaning liquid, a controller configured to control a temperature of the cleaning liquid, a wafer holder configured to hold and rotate a wafer, a first nozzle above the wafer and configured to spray the cleaning liquid on a top surface of the wafer, and a second nozzle below the wafer and configured to spray the cleaning liquid on a bottom surface of the wafer.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. An apparatus, comprising:
a wafer holder configured to hold and rotate a wafer;
a first nozzle above the wafer and configured to spray a first cleaning liquid on a top surface of the wafer, wherein the first cleaning liquid is generated by a cooling system and a first temperature of the first cleaning liquid is below room temperature; and
a second nozzle below the wafer and configured to spray a second cleaning liquid on a bottom surface of the wafer, wherein the second cleaning liquid is generated by the cooling system and a second temperature of the second cleaning liquid is below room temperature.

2. The apparatus of claim 1, further comprising:
a third nozzle below the wafer and configured to spray the second cleaning liquid on the bottom surface of the wafer, wherein the second and third nozzles are on opposite sides of the wafer holder.

3. The apparatus of claim 1, further comprising:
a pipe connecting the first nozzle to the cooling system, wherein the pipe is configured to deliver the first cleaning liquid to the first nozzle.

4. The apparatus of claim 3, further comprising:
a valve on the pipe and configured to control a flow rate of the first cleaning liquid delivered to the first nozzle.

5. The apparatus of claim 1, further comprising:
a pipe connecting the second nozzle to the cooling system, wherein the pipe is configured to deliver the second cleaning liquid to the second nozzle.

6. The apparatus of claim 1, wherein each of the first and second temperatures ranges from about 5 ℃ to about 15 ℃.

7. The apparatus of claim 1, further comprising:
a first temperature sensor disposed on the first nozzle and configured to measure the first temperature; and
a second temperature sensor disposed on the second nozzle and configured to measure the second temperature.

8. The apparatus of claim 1, wherein a difference between the first temperature and the second temperature ranges from about 0 ℃ to about 5 ℃.

9. The apparatus of claim 1, wherein the first and second cleaning liquids comprise deionized water generated by the cooling system.

10. A method, comprising:
loading a wafer in a cleaning apparatus;
generating, with a cooling system, a cleaning liquid having a temperature below room temperature;
delivering the cleaning liquid to a first nozzle above the wafer and a second nozzle below the wafer; and
cleaning a top surface of the wafer with the cleaning liquid using the first nozzle and a bottom surface of the wafer with the cleaning liquid using the second nozzle.

11. The method of claim 10, further comprising:
measuring the temperature of the cleaning liquid with a temperature sensor on the first nozzle.

12. The method of claim 10, further comprising:
controlling a flow rate of the cleaning liquid with a valve on a pipe connected to the first nozzle.

13. The method of claim 10, wherein cleaning the top surface of the wafer comprises:
rotating the wafer with a wafer holder;
spraying the cleaning liquid on the top surface of the wafer; and
moving the first nozzle from an edge of the wafer to a center of the wafer while rotating the wafer.

14. The method of claim 10, wherein generating the cleaning liquid with the cooling system comprises controlling the temperature of the cleaning liquid between about 5 ℃ and about 15 ℃.

15. The method of claim 10, further comprising measuring the temperature of the cleaning liquid flowing out of the cooling system with a temperature sensor.

16. A system, comprising:
a cooling system configured to generate a cleaning liquid;
a controller configured to control a temperature of the cleaning liquid;
a wafer holder configured to hold and rotate a wafer;
a first nozzle above the wafer and configured to spray the cleaning liquid on a top surface of the wafer; and
a second nozzle below the wafer and configured to spray the cleaning liquid on a bottom surface of the wafer.

17. The system of claim 16, further comprising:
a pipe connecting the first nozzle to the cooling system, wherein the pipe is configured to deliver the cleaning liquid to the first nozzle; and
a valve on the pipe and configured to control a flow rate of the cleaning liquid.

18. The system of claim 16, wherein the temperature of the cleaning liquid ranges from about 5 ℃ to about 15 ℃.

19. The system of claim 16, further comprising:
a first temperature sensor disposed on the first nozzle and configured to measure a first temperature of the cleaning liquid delivered to the first nozzle; and
a second temperature sensor disposed on the second nozzle and configured to measure a second temperature of the cleaning liquid delivered to the second nozzle, wherein a difference between the first temperature and the second temperature ranges from about 0 ℃ to about 5 ℃.

20. The system of claim 16, wherein the cooling system comprises:
a first pipe configured to hold a refrigerant, wherein a diameter of the first pipe ranges from about 5 mm to about 10 mm;
a second pipe configured to hold the cleaning liquid;
a temperature sensor on the second pipe and configured to measure a temperature of the cleaning liquid flowing out of the second pipe; and
a cooling tank configured to hold the first and second pipes.
